(19) United States
(12) Patent Application Publication
(10) Pub. No.: US 2001/0045661 A1
(43) Pub. Date: Nov. 29, 2001

(54) COMPOSITE METALLIZATION PROCESS FOR FILLING HIGH ASPECT RATIO CONTACT HOLES

(76) Inventors: CHI-CHENG YANG, HSIN-CHU CITY (TW); JENN-TARNG LIN, HSIN-CHU CITY (TW)

Correspondence Address: RABIN & CHAMPAGNE, PC, 1101 14TH STREET, NW, SUITE 500, WASHINGTON, DC, 20005, US

(21) Appl. No.: 09/190,271

(22) Filed: Nov. 13, 1998

Related U.S. Application Data
(62) Division of application No. 08/727,111, filed on Oct. 8, 1996, now abandoned.
(60) Provisional application No. 60/009,355, filed on Dec. 29, 1995.

(51) Int. Cl. H01L 23/48

(52) U.S. Cl. 257/763; 257/750; 257/751

(57) ABSTRACT

A process has been developed in which high aspect ratio contact holes can be successfully filled, without voids, using a composite metallization layer. After adhesive and barrier layers are deposited, an additional titanium adhesive layer is deposited, for purposes of improving the adhesion of subsequent, overlying metallizations to underlying device structures. A two step aluminum deposition process is then employed, using an initial cold deposition followed by a hot aluminum deposition. The hot aluminum deposition process results in complete filling of the high aspect ratio contact hole, and also allows the formation of a titanium-aluminum intermetallic layer at the interface of the titanium adhesive layer and the initial, cold aluminum deposition layer.

This application claims priority from provisional application Ser. No. 60/009,355, filed Dec. 29, 1995.

### BACKGROUND OF THE INVENTION

1. Field of the Invention

The present invention relates to the methods used to fabricate semiconductor devices, and more specifically to methods used to form metal contacts.

2. Description of the Related Art

The semiconductor industry is continually striving to improve the performance of silicon devices. The trend to miniaturization, resulting in silicon devices with sub-micron features, has improved performance. Reductions in critical device features translate to decreases in device resistances and capacitances, which in turn result in performance benefits. The attainment of submicron features has in part been realized by advances in specific semiconductor fabrication disciplines, such as photolithography and dry etching. For example, more advanced exposure cameras, as well as development of more sensitive photoresist materials, have allowed sub-micron images to be routinely produced in photoresist masking layers. In addition, more advanced dry etching tools and processes have allowed the sub-micron images in photoresist layers to be successfully transferred to underlying semiconductor materials.

The creation of sub-micron semiconductor device features can present areas of concern not encountered when fabricating devices having larger features. For example, sub-micron diameter contact holes used to connect wiring metallizations to underlying silicon regions are more difficult to fill using conventional metal deposition procedures than are contact holes with larger diameter openings. As the aspect ratio of contact holes increases, conventional sputtering processes have difficulty in adequately filling the contact holes. Incomplete metal fills can lead to yield or reliability problems due to increased current densities present due to the thinner metal in the contact hole. This problem has been addressed by replacing sputtered metallizations by more conformal, chemical vapor deposition (CVD) metallizations. Chemical vapor deposited layers offer improved conformality when compared to sputtered counterparts, thus providing a better contact hole fill. However, the use of chemically vapor deposited metallization precludes the use of an aluminum metallurgy, since it is very difficult to chemically vapor deposit aluminum. The use of chemical vapor deposited tungsten would overcome the contact hole fill difficulties, but the higher resistivity of tungsten degrades performance. Therefore, efforts have been directed to improving the fill characteristics of sputtered aluminum.

Advances in aluminum deposition processes have included a two step process in which the initial deposition is performed cold, at a temperature below about 100° C., followed by a second deposition at a temperature between about 250 to 400° C. The initial cold deposition provides a continuous seed layer, while the higher temperature cycle offers depositing aluminum atoms, with increased mobility, resulting in improved fill characteristics. In U.S. Pat. No. 4,970,176, Tracy, et al., describe a two step, cold and hot, sputtered aluminum deposition process. It would be desirable, however, to deposit aluminum in a manner that has better adhesion than is obtained using the methods described in the patent to Tracy, et al.

Summary of the Preferred Embodiments.

Aspects of the present invention include an improved process for deposition of metal contact films including an underlying layer of titanium, preferably formed using a collimated deposition process, to provide a better surface for cold aluminum adhesion. This invention will also describe a two step aluminum sputtering process, resulting in optimum metal filling of high aspect ratio contact holes, with the hot deposition stage being performed at a temperature high enough to form an intermetallic layer of TiₓAl_{y}, again resulting in improved adhesion between the aluminum fill and underlying materials.

One aspect of this invention provides a method of depositing a composite metallization that results in successful filling of high aspect ratio contact holes.

Another aspect of this invention uses an underlying adhesion layer as part of the composite metallization layer to provide wettability for subsequent layers of the composite metallization layer.

Yet another aspect of this invention uses sputtered aluminum as part of the composite metallization layer to fill the high aspect ratio contact holes.

Another aspect of this invention uses a two stage, sputtered aluminum deposition process consisting of an initial, cold aluminum deposition followed by a higher temperature aluminum deposition.

In accordance with the present invention, a method is described for fabricating silicon devices using a composite metallization sequence to successfully fill high aspect ratio contact holes. A contact hole is opened in a dielectric layer to expose a region in a semiconductor substrate. Preferably, a collimated, sputtered adhesive layer of titanium, followed by a collimated, sputtered barrier layer of titanium nitride, are deposited. In a particularly preferred embodiment, rapid thermal processing, preferably using an ammonia ambient, is performed to improve the barrier effectiveness of the titanium nitride layer, preferably followed by another deposition of collimated, sputtered titanium, to be used as a wetting layer for subsequent overlying layers. A two step sputtered aluminum deposition is performed, consisting of an initial layer sputtered at a low temperature, followed by another layer sputtered at a higher temperature, resulting in successful filling of the high aspect ratio contact hole, as well as resulting in excellent adhesion between the composite metallization and the underlying substrate. Photolithographic and dry etching procedures are preferably used to create the desired composite metallization pattern.

### BRIEF DESCRIPTION OF THE DRAWINGS

The objects and other advantages of this invention are best understood by the following descriptions of the preferred embodiments of the present invention, together with the attached drawings, which include:

FIG. 1 schematically illustrates in cross-section a metal oxide semiconductor field effect transistor (MOSFET) at a stage prior to contact hole filling.

FIGS. 2-5 schematically illustrate in cross-section specific stages of fabrication of the metal filled, high aspect ratio contact hole.

### DESCRIPTION OF THE PREFERRED EMBODIMENTS

The method of filling high aspect ratio contact holes with a composite metallization layer will now be described. This invention can be applied to MOSFET devices that are currently being manufactured in the industry, therefore only the specific areas unique to understanding this invention will be covered in detail.

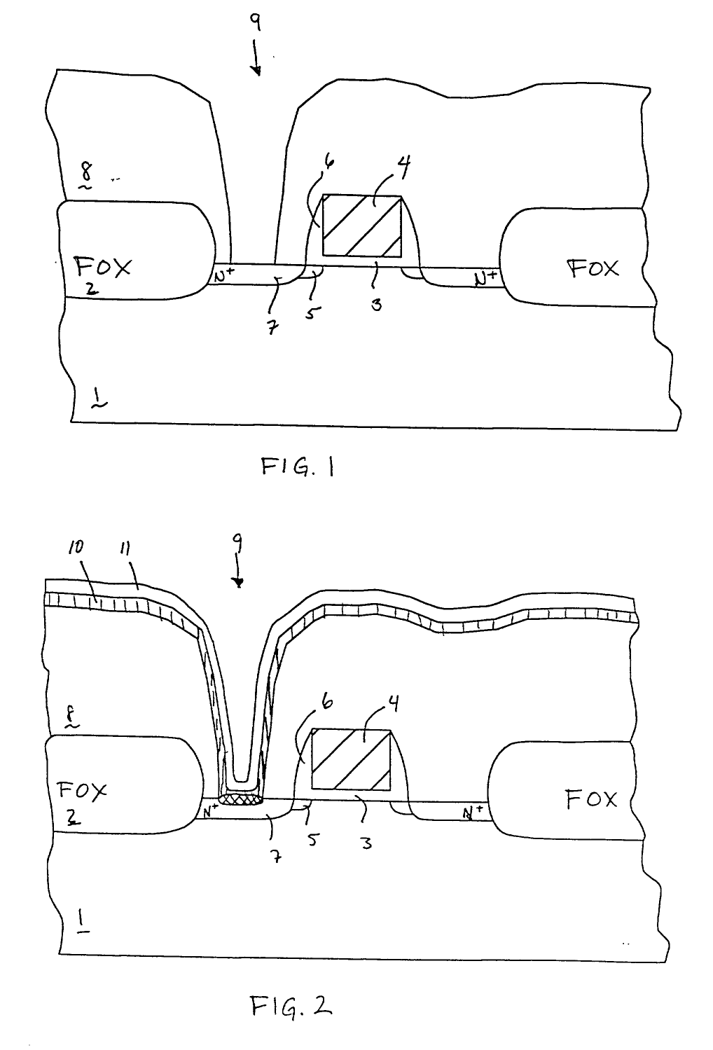

A typical N-channel field effect transistor (NFET) device, having high aspect ratio contact holes, will be used as the vehicle to describe the filling of contact holes with a composite metallization. FIG. 1 shows a P-type substrate 1 of single crystal silicon with a <100> crystallographic orientation. Thick field oxide (FOX) regions 2 are created and used for device isolation. The FOX regions 2 are formed by first patterning silicon nitride and silicon dioxide layers to form a field oxidation mask via use of standard photolithographic and selective anisotropic reactive ion etching (RIE) processes. After photoresist removal, via plasma oxygen ashing followed by careful wet cleans, a thermal oxidation is performed to create a silicon dioxide FOX region 2 having a thickness of between about 4000 to 6000 Å. After removal of the composite insulator mask using hot phosphoric acid for the silicon nitride layer and buffered hydrofluoric acid solution for the underlying silicon dioxide layer, a thin silicon dioxide gate insulator 3 is grown at a temperature between about 800 to 1000° C. to a thickness between about 50 to 300 Å. A polysilicon layer is next deposited using low pressure chemical vapor deposition (LPCVD) processing at a temperature between about 500 to 700° C. to a thickness between about 1500 to 4000 Å. The polysilicon layer can be rendered conductive (e.g., N-type) using an in situ doping process by adding either phosphine or arsine to the silane deposition environment. The polysilicon might alternately be deposited intrinsically and doped via implantation of phosphorus or arsenic ions at an energy of between about 50 to 100 KeV to a dose of 1×10¹⁵ to 1×10¹⁶ atoms/cm². Standard photolithographic and RIE procedures using a chlorine chemistry are preferably used to create polysilicon gate structure 4, shown schematically in FIG. 1.

After photoresist removal, again via plasma oxygen ashing followed by careful wet cleans, an implantation of either arsenic or phosphorus ions is performed at an energy of about 30 to 80 KeV to a dose between about 1×10¹² to 1×10¹³ atoms/cm² to create a lightly doped source and drain region 5. A silicon oxide layer is next deposited, preferably using either LPCVD or plasma enhanced chemical vapor deposition (PECVD). The silicon oxide layer, preferably formed using tetraethylorthosilicate (TEOS) as a source, is deposited at a temperature between about 400 to 800° C. to a thickness between about 1500 to 4000 Å. An RIE process is next performed using CHF₃ as an etchant to create silicon oxide sidewall spacer 6. Heavily doped source and drain regions 7 are preferably created via ion implantation of arsenic at an energy between about 50 to 100 KeV to a dose between about 1×10¹⁴ to 5×10¹⁵ atoms/cm². After deposition of another silicon oxide layer 8 via use of either LPCVD, PECVD, or atmospheric pressure chemical vapor deposition (APCVD) deposition at a temperature between about 400 to 800° C. to a thickness between 5000 to 10000 Å, contact hole 9 is created. This is shown in FIG. 1. Contact hole 9 is opened to source or drain region 7 via use of standard photolithographic and RIE processing using CHF₃ as an etchant. Photoresist removal is accomplished via plasma oxygen ashing and careful wet cleans. Aggressive device designs of the type needed for performance enhancements rely on the use of small diameter contact hole openings. Small contact hole openings, particularly for deep contact holes 9, result in contact holes with high aspect ratios (depth of the hole divided by the diameter of the hole) that can be difficult to fill with conventional contact metallizations.

The adhesive and barrier layers preferred in accordance with the present invention for successful fabrication of metal filled, high aspect ratio contact holes, are formed next. A surface pre-clean procedure using a buffered hydrofluoric acid solution removes any native oxide from the surface of source or drain region 7. A layer of titanium 10 used to enhance the adhesion of subsequent overlying metallizations to the underlying structure, is preferably deposited using collimated d.c. sputtering to a thickness between about 200 to 400 Å. The use of collimated sputtering results in a thicker titanium coating at the bottom of the contact hole 9 than is present on the sides of the contact hole. Collimated r.f sputtering is again used to deposit a barrier layer to separate subsequent overlying metallizations from the underlying structure. The titanium nitride layer 11 is deposited to a thickness between about 800 to 1200 Å. The collimated procedure allows a thicker barrier layer to be present at the bottom of contact hole 9 where the barrier is most needed. These adhesion and barrier layers are shown schematically in FIG. 2. The effectiveness of titanium nitride layer 11 as a barrier is enhanced by performing a rapid thermal process (RTP). The RTP is performed initially at a temperature between about 550 to 650° C. for between about 45 to 75 seconds, followed by a second anneal step at a temperature between about 725 to 775° C. for a time between about 10 to 30 seconds. Each of the steps of the RTP is preferably performed in a nitrogen-ambient and most preferably in an ammonia ambient. This RTP procedure enhances the barrier effectiveness of titanium nitride layer 11 by placing additional nitrogen in the layer. The RTP cycle also results in the formation of titanium disilicide 12 at the interface between titanium layer 10 and the source or drain interface 7.

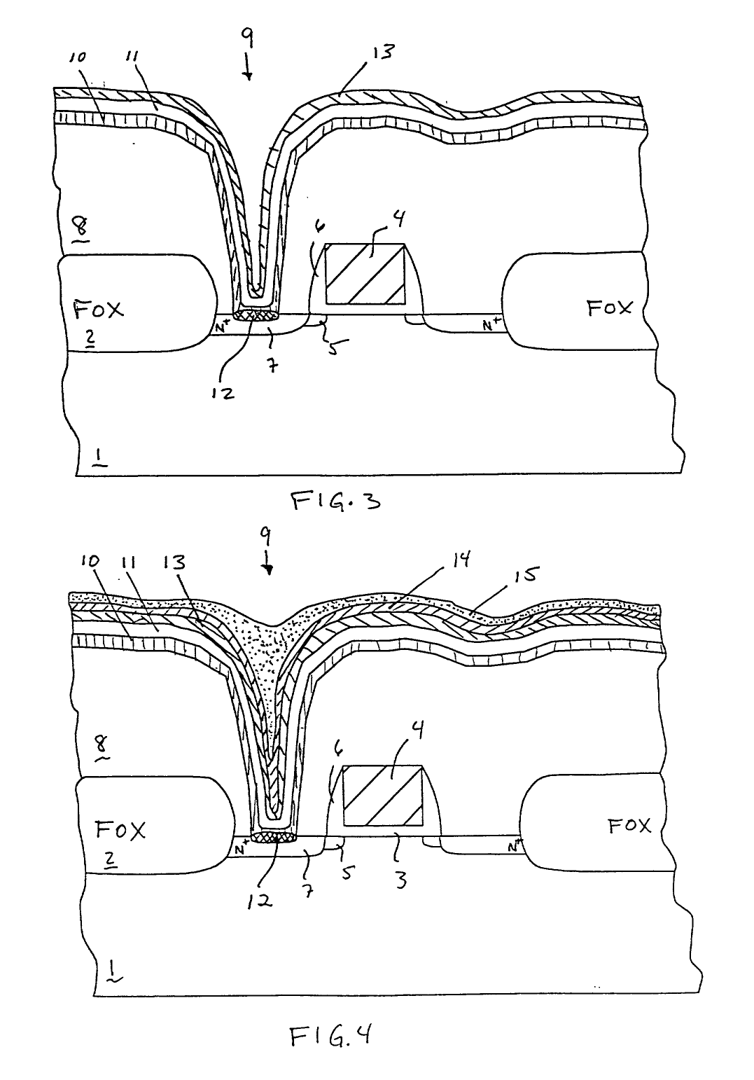

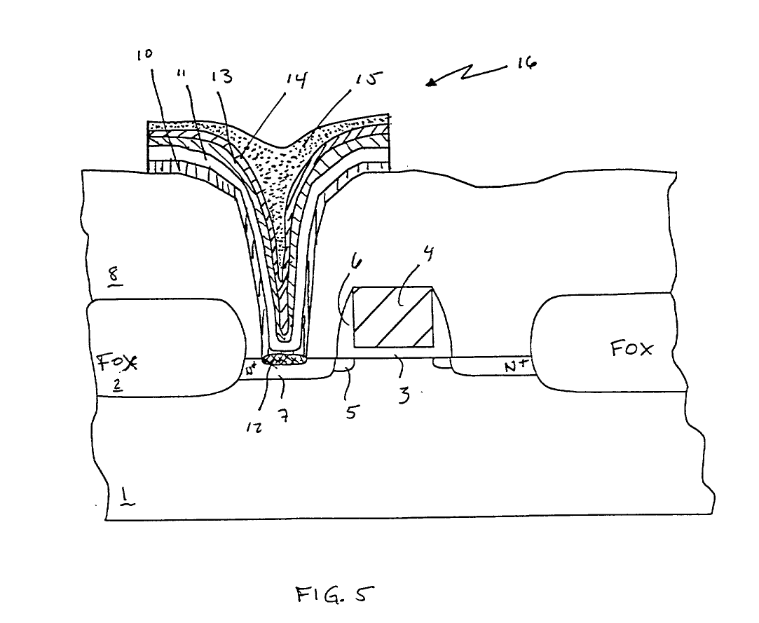

Collimated d.c. sputtering is employed to deposit another layer of titanium 13 to a thickness between about 800 to 1500 Å. This layer, shown in FIG. 3, is used to provide an adhesive or wetting layer for subsequent overlying aluminum metallizations. The filling of high aspect ratio contact hole 9 with aluminum can now proceed. First, a layer of aluminum 14 is d.c. sputtered, preferably without the use of collimation, to a thickness between about 2000 to 3000 Å. This deposition is most preferably performed at a temperature less than 100° C. This layer, deposited to about one half of the desired aluminum thickness, will typically exhibit poor fill characteristics, shown schematically in FIG. 4, but will generally provide a continuous seed layer for a subsequent, overlying aluminum layer. The remaining half of the desired aluminum thickness is next deposited, again preferably using non-collimated d.c. sputtering, at a temperature between about 475 to 525° C. to a thickness between about 2000 to 3000 Å. The aluminum layer 15 deposited at elevated temperatures results in a successful fill of contact hole 9, shown schematically in FIG. 4. This is accomplished by the increased mobility of aluminum atoms at the elevated deposition temperature. In addition, the elevated deposition temperature results in the formation of a TiₓAl_{y} intermetallic compound at the interface between titanium layer 13 and aluminum layer 14, resulting in an adhesion improvement. The layer of intermetallic compound is not shown in FIG. 4. Standard photolithographic and RIE processing using chlorine as an etchant are preferably employed to define the finished metal structure 16, shown in FIG. 5. Plasma oxygen ashing is used to remove the photoresist after the metallization is patterned.

This process for filling high aspect ratio contact holes with a composite metallization, although shown as applied to an NFET device, can also be applied to P-channel (PFET) devices, complimentary devices (CMOS) devices, bipolar and BiCMOS devices.

While this invention has been particularly shown and described with reference to the preferred embodiments thereof, it will be understood by those skilled in the art that various changes in form and details may be made without departing from the spirit and scope of the invention.

What is claimed is:

1. A method for fabricating a device on a semiconductor substrate, comprising the steps of:
providing a device element on the semiconductor substrate;
depositing a dielectric layer on the semiconductor substrate, including on the device element;
anisotropically etching the dielectric layer to create a contact hole to a specific region of the device element;
surface cleaning the specific region of the device element;
depositing a first adhesive layer at least on the specific region of the device element;
depositing a barrier layer on the first adhesive layer;
depositing a second adhesive layer on the barrier layer;
depositing a first metal fill layer on the second adhesive layer;
depositing a second metal fill layer on the first metal fill layer, completely filling said contact hole; and
patterning at least the second metal fill layer to form an interconnect metallization structure.

2. The method of claim 1, wherein the device element on said semiconductor substrate is an N-type field effect transistor with the specific region of the device element being an N-type source or drain region.

3. The method of claim 1, wherein said dielectric layer is silicon oxide deposited using LPCVD, PECVD or APCVD at a temperature between about 400 to 800° C. to a thickness between about 5000 to 10000 Å.

4. The method of claim 1, wherein the contact hole is formed via anisotropic RIE processing using CHF₃ as an etchant, with the contact hole having a size between about 0.3 to 0.6 μm across, resulting in an aspect ratio of between about 1.0 to 3.0.

5. The method of claim 1, wherein the first adhesive layer is titanium deposited using collimated d.c. sputtering to a thickness between about 200 to 400 Å.

6. The method of claim 1, wherein the barrier layer is titanium nitride deposited using collimated d.c. sputtering to a thickness between about 800 to 1200 Å.

7. The method of claim 1, further comprising a step of rapid thermal processing said barrier layer deposited on the first adhesive layer, wherein the rapid thermal processing is performed in a nitrogen-containing ambient, first at a temperature between about 575 to 625° C. for a time about 45 to 75 seconds, then at a temperature between about 725 to 775° C. for a time between about 10 to 30 seconds.

8. The method of claim 1, wherein the second adhesive layer is titanium deposited using collimated d.c. sputtering to a thickness between about 800 to 1500 Å.

9. The method of claim 1, wherein the first metal fill layer is aluminum deposited using d.c. sputtering at a temperature below 100° C. to a thickness between about 2000 to 3000 Å.

10. The method of claim 1, wherein the second metal fill layer is aluminum deposited using r.f. sputtering at a temperature between about 475 to 525° C. to a thickness between about 2000 to 4000 Å.

11. The method of claim 1, wherein the interconnect metallization structure is formed via RIE processing using Cl₂ as an etchant.

12. A method for fabricating a MOSFET device on a semiconductor substrate, comprising the steps of:
providing a device element on the semiconductor substrate;
depositing a dielectric layer on the semiconductor substrate, including on the device element;
anisotropically etching the dielectric layer to create a contact hole to a specific region of the device element;
surface cleaning the specific region of the device element;
depositing a first titanium adhesive layer at least on the specific region of the device element;
forming a titanium nitride barrier layer on the first titanium adhesive layer;
depositing a second titanium adhesive layer on the titanium nitride barrier layer;
cold depositing a first metal fill layer comprising aluminum on the second titanium adhesive layer;
hot depositing a second metal fill layer comprising aluminum on the first metal fill layer, completely filling said contact hole while forming an intermetallic layer between the second titanium adhesive layer and the aluminum of the first metal fill layer at an interface between the second titanium adhesive layer and the first metal fill layer; and
patterning at least the second metal fill layer to form a metal interconnect structure.

13. The method of claim 12, wherein the device element on said semiconductor substrate is an N-type field effect transistor with the specific region of the device element being an N-type source or drain region.

14. The method of claim 12, wherein said dieletric layer is silicon oxide deposited using LPCVD, PECVD or APCVD at a temperature between about 400 to 800° C. to a thickness between about 5000 to 10000 Å.

15. The method of claim 12, wherein the contact hole is formed via anisotropic RIE processing using CHF₃ as an etchant to a depth of between 5000 to 10000 Å, with the contact hole having a size between about 0.3 to 0.6 μm across, resulting in an aspect ratio of between about 1.0 to 3.0.

16. The method of claim 12, wherein the first titanium adhesive layer is deposited using collimated d.c. sputtering to a thickness between about 200 to 400 Å.

17. The method of claim 12, wherein the titanium barrier layer is deposited using collimated d.c. sputtering to a thickness between about 800 to 1200 Å.

18. The method of claim 12, further comprising a step of rapid thermal processing said barrier layer deposited on the first adhesive layer, wherein the rapid thermal processing is performed in an ammonia ambient, first at a temperature between about 575 to 625° C. for a time about 45 to 75 seconds, then at a temperature between about 725 to 775° C. for a time between about 10 to 30 seconds.

19. The method of claim 12, wherein the second titanium adhesive layer is deposited using collimated d.c. sputtering to a thickness between about 800 to 1500 Å.

20. The method of claim 12, wherein the first metal fill layer is deposited at a temperature below 100° C. to a thickness between about 2000 to 3000 Å.

21. The method of claim 12, wherein the second metal fill layer is deposited using r.f sputtering at a temperature between about 475 to 525° C. to a thickness between about 2000 to 4000 Å.

22. The method of claim 12, wherein the intermetallic is formed during the deposition of the second metal fill layer at a temperature between 475 to 525° C.

23. The method of claim 12, wherein the interconnect metallization structure is formed via RIE processing using CH₃ as an etchant.

24. A MOSFET device structure, comprising:
field oxide regions on a surface of a semiconductor substrate;
a device region between the field oxide regions;
a polysilicon gate structure on the semiconductor substrate;
source and drain regions in the surface of the semiconductor substrate on either side of the polysilicon gate structure;
an insulator layer located on the source and drain regions, on the polysilicon gate structure, and on the field oxide region; and
a contact hole in the insulator layer, to the source and drain region, filled with a composite metallization layer.

25. The MOSFET device structure of claim 24, wherein the contact hole has a depth between about 5000 to 10000 Å, with an opening between about 0.3 to 0.6 μm across, resulting in an aspect ratio between about 1.0 to 3.0.

26. The MOSFET device structure of claim 24, wherein the composite metallization layer comprises:
a first titanium adhesive layer with a thickness between about 200 to 400 Å;
a titanium nitride barrier layer with a thickness between about 800 to 1200 Å;
a second titanium adhesive layer with a thickness between about 800 to 1500 Å;
an intermetallic layer of titanium and aluminum;
a first aluminum layer with a thickness between about 2000 to 3000 Å; and
a second aluminum layer with a thickness between about 2000 to 3000 Å.
